(19) United States
(12) Patent Application Publication
(10) Pub. No.: US 2021/0153330 A1
(43) Pub. Date: May 20, 2021

(54) REMOTELY CONTROLLABLE SNAP-IN HIGH-POWER CONTROL MODULE

(71) Applicant: Audio Accessories Group, LLC, Tempe, AZ (US)

(72) Inventors: Larry Vansickel, Phoenix, AZ (US); Wang Hai, NINGBO (CN); Gu Wendong, NINGBO (CN); Zhou Liang, NINGBO (CN)

(21) Appl. No.: 17/107,456

(22) Filed: Nov. 30, 2020

Related U.S. Application Data
(63) Continuation-in-part of application No. 15/949,518, filed on Apr. 10, 2018.

(51) Int. Cl. H05B 47/19; H05K 5/00; G05B 15/02

(52) U.S. Cl. CPC H05B 47/19; H05K 5/0017; H05K 5/0073; G05B 15/02; H05K 5/0039; H05K 5/0069

(57) ABSTRACT

A control module with manual switches for controlling the ON/OFF status, brightness, and flashing pattern of a high-power variable current electrical device. The control module is intended for use with the interlocking modular frames of U.S. patent application Ser. No. 15949518, but may be used with other switch panels as well. The control module also includes at least one radio transceiver configured to receive communications from a smartphone application for controlling a high-power variable current electrical device attached to the control module. In some embodiments, the smartphone application may provide more control options than are provided by the manual switches on the front of the control module.

### RELATIONSHIP TO OTHER APPLICATIONS

This application is a continuation in part of patent application Ser. No. 15949518 filed Apr. 10, 2018 to at least one common inventor.

### FIELD OF ART

The present invention relates to a remotely controllable snap-in high power control module for variable current electrical devices. The present invention more particularly relates to multifunctional switches that snap into modular frames, that can handle high power, and that are remotely controllable via long-range and/or short-range radio.

### BACKGROUND OF THE INVENTION

High power variable current electrical devices include light bars, heaters, motors, and the like. The embodiment of a variable current electrical device illustrated herein is a light bar, but the invention is not so limited. Those of skill in the art, enlightened by this disclosure, will be aware of a wide variety of variable current electrical devices. Light bars include arrays of various illumination sources that can produce light in various colors, flashing patterns, and intensity levels. Examples of light bars include, without limitation, light bars for emergency vehicles, decorative light bars for entertainment venues, and vehicle decorations on sport vehicles. Controllers for light bars are conventionally only manually operated, which can create inconvenience for the user.

### SUMMARY OF THE INVENTION

The present invention provides a control module with manual switches for controlling the ON/OFF status, brightness, and flashing pattern of a light bar. The control module is intended for use with the interlocking modular frames of US patent application Ser. No. 15949518, but may be used with other switch panels as well. The control module also includes at least one radio transceiver configured to receive communications from a smartphone application for controlling a light bar attached to control module. In some embodiments, the smartphone application may provide more control options than are provided by the manual switches on the front of the control module. The smartphone may communicate with the control module via cellular telephone links and/or Bluetooth® or other short-range radio. Devices other than smart phones, having communication functionality and able to run a software application, may be substituted for the smart phone. For example, tablet computers and the like may be used.

### DESCRIPTION OF THE FIGURES OF THE DRAWINGS

The present invention will hereinafter be described in conjunction with the following drawing figures, wherein like numerals denote like elements, and

FIG. 1 is a front perspective view illustrating an exemplary embodiment of a remotely controllable snap-in variable current electrical device control module and a front elevation view of a smartphone in communication therewith, according to a preferred embodiment of the present invention;

FIG. 2 is a rear perspective view illustrating the exemplary embodiment of the remotely controllable snap-in variable current electrical device control module of FIG. 1, according to a preferred embodiment of the present invention;

FIG. 3 is a top plan view illustrating the exemplary embodiment of the remotely controllable snap-in variable current electrical device control module of FIG. 1, according to a preferred embodiment of the present invention;

FIG. 4 is a side elevation view illustrating the exemplary embodiment of the remotely controllable snap-in variable current electrical device control module of FIG. 1, according to a preferred embodiment of the present invention;

FIG. 5 is front elevation view illustrating the exemplary embodiment of the remotely controllable snap-in variable current electrical device control module of FIG. 1, according to a preferred embodiment of the present invention;

FIG. 6 is an exploded perspective view illustrating the exemplary embodiment of the remotely controllable snap-in variable current electrical device control module of FIG. 1, according to a preferred embodiment of the present invention; and

FIG. 7 is a diagrammatic view illustrating the exemplary embodiment of the remotely controllable snap-in variable current electrical device control module of FIG. 1 in a system context, according to a preferred embodiment of the present invention.

### DETAILED DESCRIPTION OF THE INVENTION

U.S. patent application Ser. No. 15949518 is incorporated into this specification and drawings in its entirety. The hundred's digits of the reference numbers are the figure number of the figure in regard to which the referenced item is first referenced.

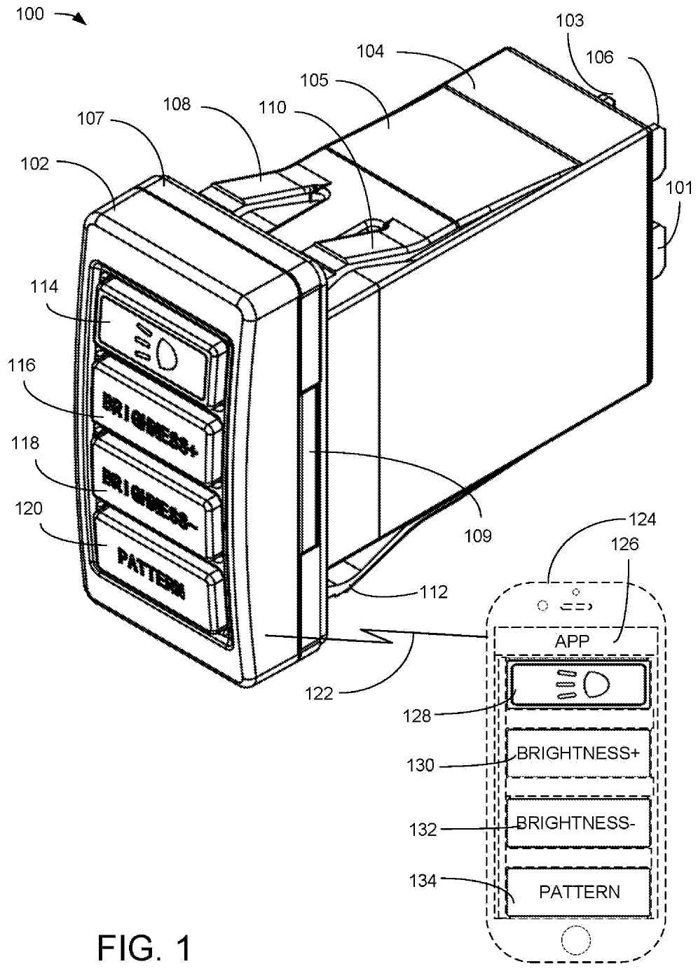

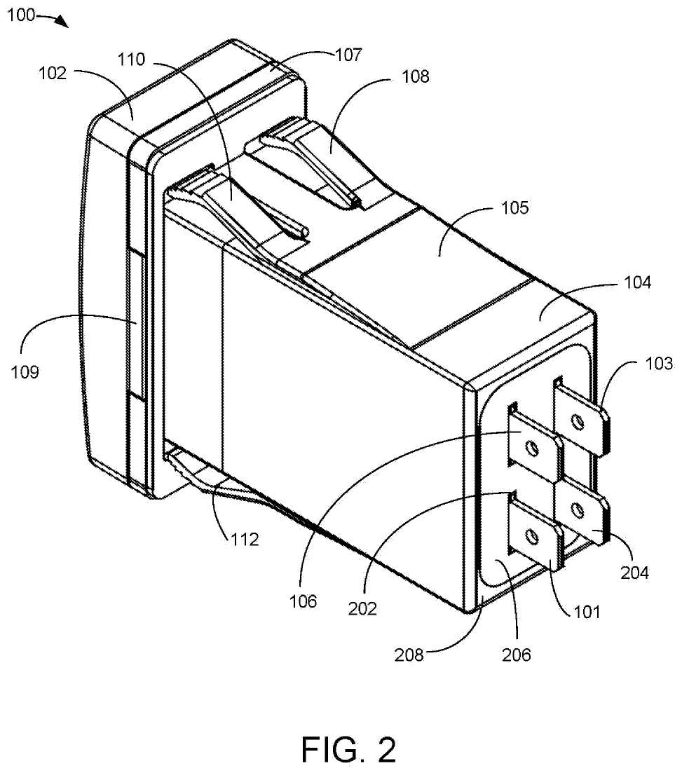

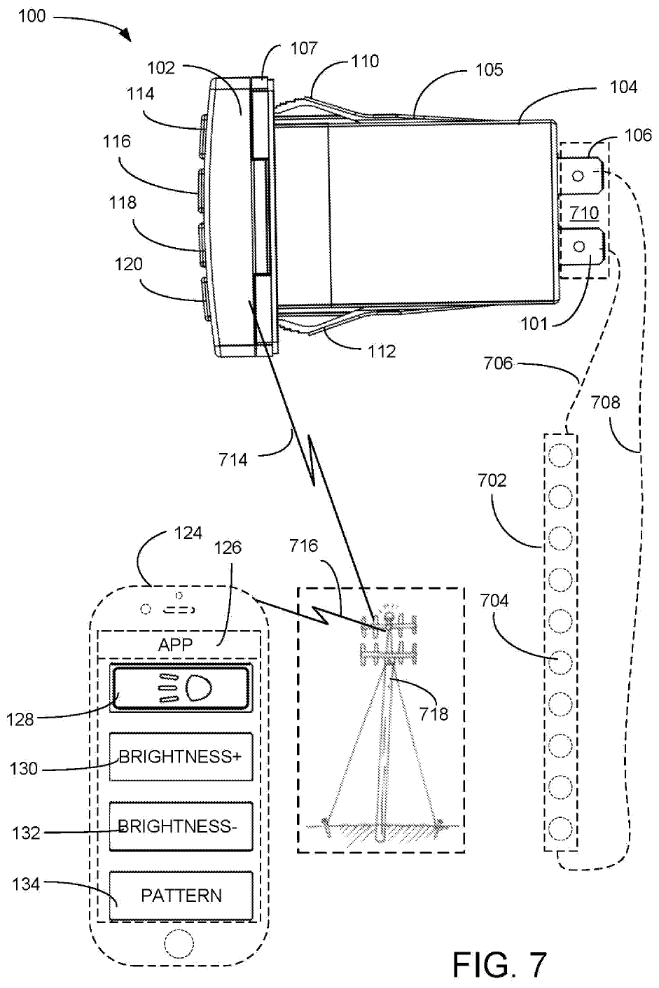

FIG. 1 is a front perspective view illustrating an exemplary embodiment of a remotely controllable snap-in variable current electrical device control module 100 and a front elevation view of a smartphone 124 in communication therewith, according to a preferred embodiment of the present invention. Control module 100 includes a snap fit housing including a rectangular shell body 104, open at both ends, and supporting features for inserting and snap fitting the control module 100 into a modular frame, such features including spring clips 108, 110, and 112, and a ramp 105. A front panel support 107 is made of one piece with the rectangular shell body 104 and includes a portion of another snap fit feature 109 for coupling front panel 102 to the rectangular shell body 104. Four prongs 101, 103, 106, and 204 (see FIG. 2) extend from the rear of the control module 100 to electrically connect the control module 100 to the light bar 702 (see FIG. 7). In various embodiments, rectangular shell body 104 may be ventilated.

Front panel 102 supports four switches 114, 116, 118, and 120. Switch 114 is the ON/OFF switch 114 for the light bar 702 (See FIG. 7). Switch 116 may be repeatedly pressed to incrementally increase the brightness of the lights 704 (see FIG. 7) on the light bar 702. Switch 118 may be repeatedly pressed to incrementally decrease the brightness of the lights 704 from the light bar 702. In a particular embodiment, switches 116 and 118 may be continuously depressed to ramp up the current and, therefore, the brightness of the lights 704 (see FIG. 7) on the light bar 702. Switch 120 may be repeatedly pressed to step through a sequence of preprogrammed patterns for flashing the lights 704 on the light bar 702 by providing an output current variation pattern. For non-limiting examples of flashing patterns, marquee lighting, alternate color flashing, Morse code flashing, etc., may be used.

In an embodiment for controlling a motor, switch 114 may still be an ON/OFF switch, switch 116 may be may be used to increase motor speed, switch 118 may be used to decrease motor speed, and switch 120 may be used to select a output current variation pattern create a variable speed pattern. In an embodiment for controlling a heater or a cooler, switch 114 may still be an ON/OFF switch, switch 116 may be may be used to increase temperature, switch 118 may be used to decrease temperature, and switch 120 may be used to select a output current variation pattern to vary temperature changes. Any electrical equipment that operates with adjustable current may be used with an embodiment of control module 100.

Smartphone 124 communicates with control module 100 via either short range radio frequency link 122 or via one or more links to cell towers 718 (see FIG. 7). Smartphone 124 has a software application 126 that is capable of presenting at least four icons 128, 130, 132, and 134, corresponding in functionality to switches 114, 116, 118, and 120, respectively. In some embodiments, a device with similar functionality, such as (without limitation) a tablet computer, may be used in place of smartphone 124. In a particular embodiment, the application may provide control of the light bar 702 beyond what is available from switches 114, 116, 118, and 120 on control module 100. For non-limiting example, synchronization of the flashing pattern to music or other audio may be provided. In various embodiments, the screen of smartphone 124 may additionally display feedback indicating the execution of control changes.

FIG. 2 is a rear perspective view illustrating the exemplary embodiment of the remotely controllable snap-in variable current electrical device control module 100 of FIG. 1, according to a preferred embodiment of the present invention. All four prongs 101, 103, 106, and 204 can be seen extending through openings 202 (one of four labeled), (illustrated here as slots 202) in backplate 206 within rear frame 208. Prongs 101, 103, 106, and 204 are preferably connectable to a four-socket plug 710 that connects to conductors 706 and 708 that connects to light bar 702. In a preferred embodiment, prongs 101 and 106 carry power to the light bar 702, including output current variation patterns. Power may be controlled as to power level to vary the brightness of the lights 704 (one of ten labeled). Prongs 103 and 204 are for power input to the control module 100. In various embodiments, respective various numbers, types, and arrangements of prongs may be used. Prongs 101, 103, 106, and 204 can conduct large amounts of current.

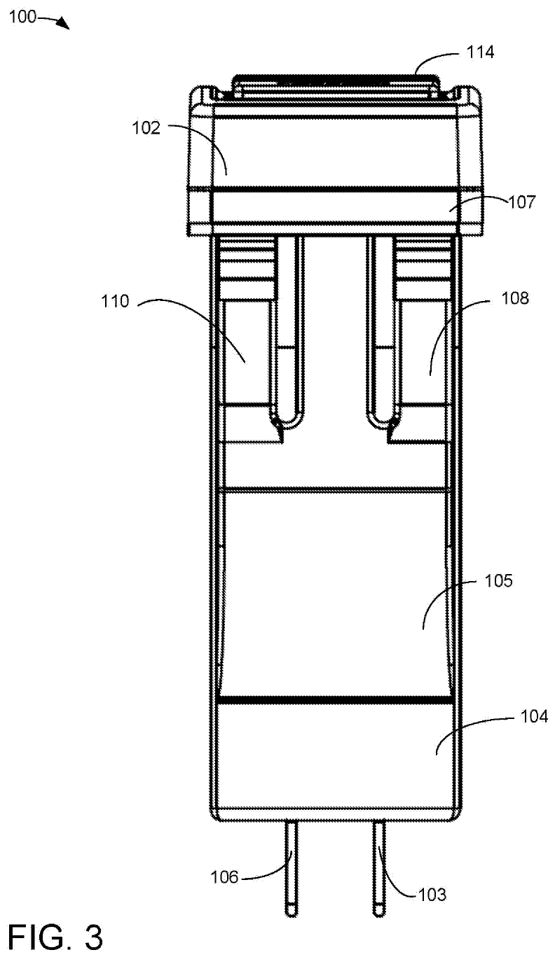

FIG. 3 is a top plan view illustrating the exemplary embodiment of the remotely controllable snap-in variable current electrical device control module 100 of FIG. 1, according to a preferred embodiment of the present invention. The bottom plan view of remotely controllable snap-in high-power control module 100 is a mirror image of FIG. 3.

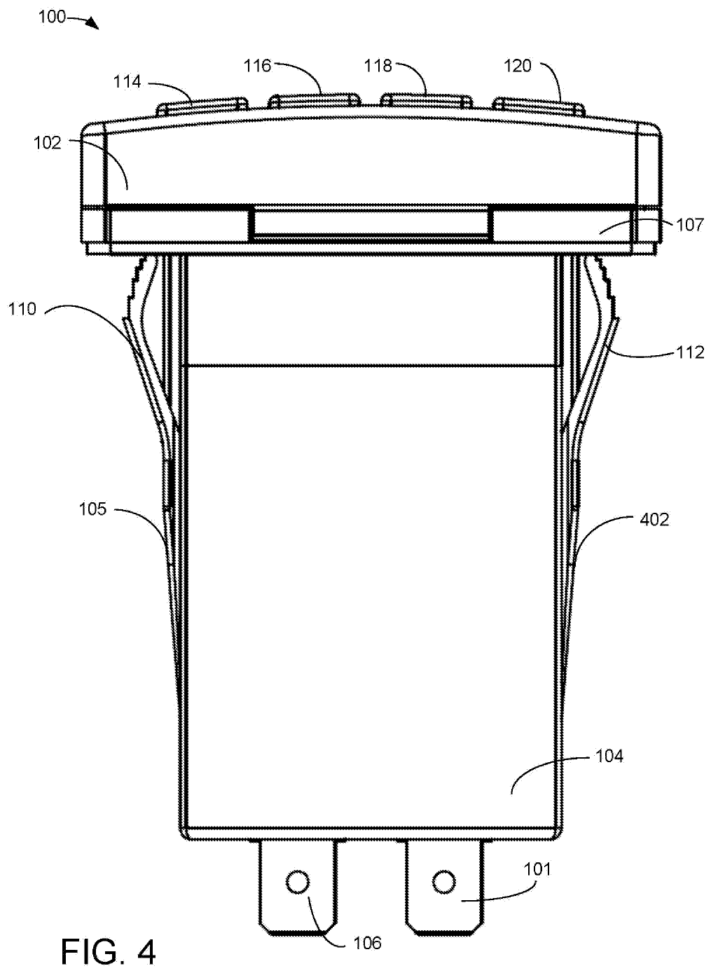

FIG. 4 is a side elevation view illustrating the exemplary embodiment of the remotely controllable snap-in variable current electrical device control module 100 of FIG. 1, according to a preferred embodiment of the present invention. Lower ramp 402 can be seen in this view. Left and right-side views of the shell body 104 are mirror images.

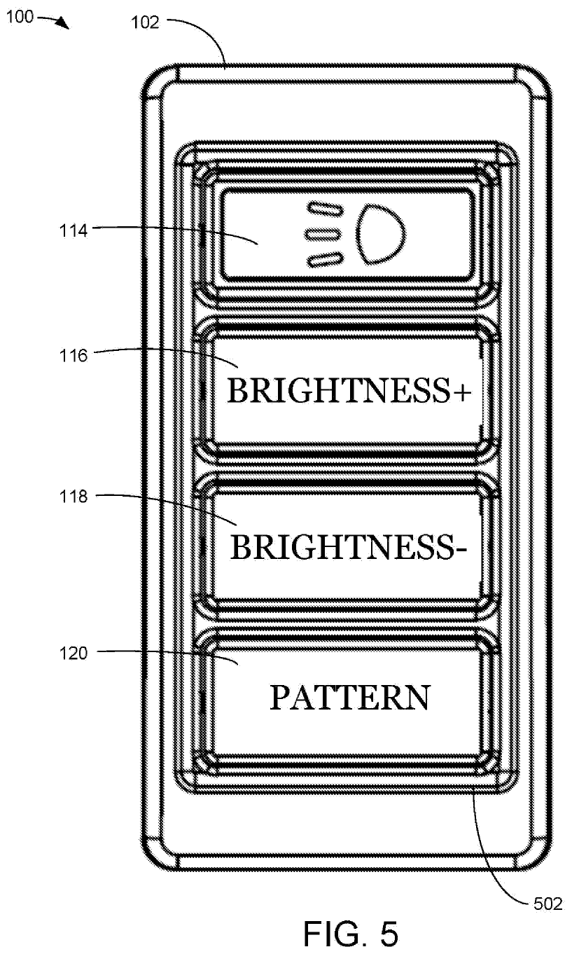

FIG. 5 is front elevation view illustrating the exemplary embodiment of the remotely controllable snap-in variable current electrical device control module 100 of FIG. 1, according to a preferred embodiment of the present invention. A better view of push button switches 114, 116, 118, and 120 can be seen within frame 502 on front panel 102.

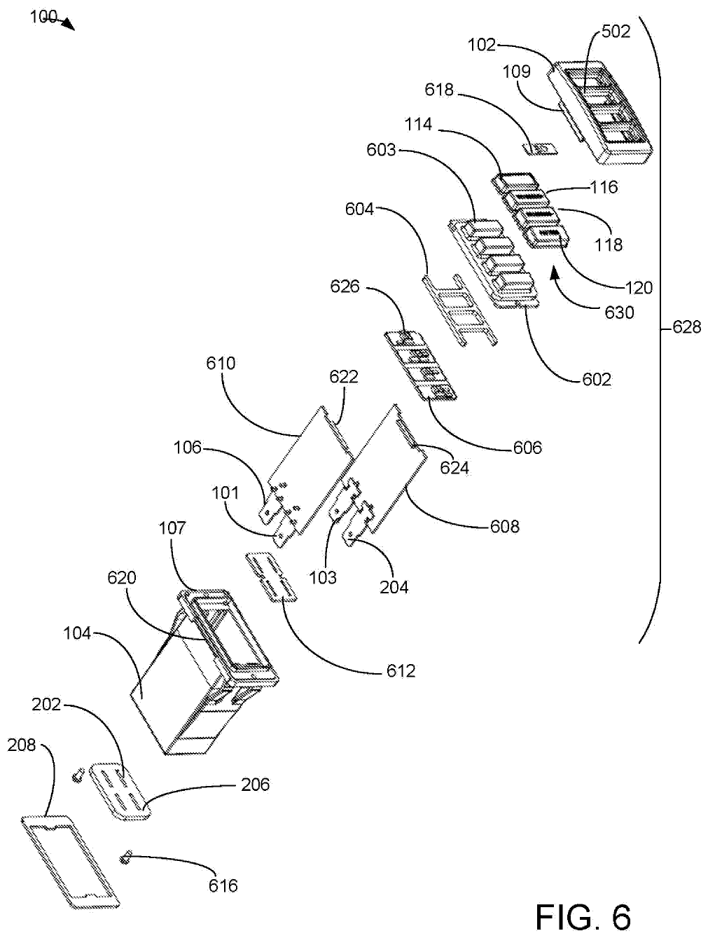

FIG. 6 is an exploded perspective view illustrating the exemplary embodiment of the remotely controllable snap-in variable current electrical device control module 100 of FIG. 1, according to a preferred embodiment of the present invention. Front panel 102 supports frame 502 and snap-fit feature 109. Frame 502 has four openings for receiving resilient push button covers 630, each supporting a label 618 for push button switches 114, 116, 118, and 120. Labels such as label 618 make manufacturing less expensive, as the words on the labels will change depending on the intended use (motors, lightbars, heaters, coolers, etc,). Push button covers 630 cover mechanical actuators 603 (one of four labeled) on actuator panel 602. Actuator support 604 aligns underneath actuator panel 602 to and on top of electro-mechanical switch panel 606. Electro-mechanical switch panel 606 is preferably a small PCB bearing the electro-mechanical switches 626 (one of four labeled) which provides electrical communication with left PCB 610 via connector 622 and with right PCB 608 via connector 624. Left PCB 610 supports prongs 106 and 101 for power output and pattern generation circuitry. Right PCB 608 supports prongs 103 and 204 for power input and supports at least one radio frequency transceiver (not shown) for communications, as well as input power regulation circuitry. For non-limiting examples, Right PCB 608 may support a short-range radio transceiver, such as a Bluetooth® transceiver and a long-range radio transceiver such as a cellular telephone transceiver. Left PCB 610 is in electrical communication with right PCB 608 via electro-mechanical switch panel 606. In various embodiments, respective various apportionment of functions between left PCB 610 and right PCB 608 may be used. PCB 608 and 610 support power MOSFETS capable of handling high current levels.

Prongs 101, 103, 106, and 204 extend through slots in insulative spacer 612 and assembly 628 is inserted into rectangular shell body 104 through an opening in front panel support 107. Snap fit feature 109 snaps into snap fit receiver 620. A minor image snap fitting is also located on the opposing side of front panel support 107. Prongs 101, 103, 106, and 204 extend through slots 202 one of four labeled) in backplate 206 and are the backplate 206 is secured with screws 616 (one of two labeled). Rear frame 208 is snap fit onto the rear end of rectangular shell body 104.

FIG. 7 is a diagrammatic view illustrating the exemplary embodiment of the remotely controllable snap-in high-power control module 100 of FIG. 1 in a system context, according to a preferred embodiment of the present invention. Light bar 702 supports at least one array of lights 704 (one often labeled) and is hard-wired to control module 100 via conductors 706 and 708 ending in four-socket plug 710. Light bar 702 may be any type of light bar, with any number, lamp type or types, and any arrangement of lights 704 installed. In various embodiments, respectively various arrangements, sizes, and shapes of sockets may be used in plug 710. Smartphone 124 software application 126 communicates with the control module 100 via a link to a cell phone tower 718 and a further link 714 from one or more cell phone towers 718 to control module 100. In a particular embodiment cellular phone tower 718 functionality may be on orbit around Earth.

The following claims include some functional claiming and do not contain any statements of use.

We claim:

1. A remotely controllable snap-in variable current electrical device controller system comprising:
a. a control module having a snap fit housing configured to engage a modular frame;
b. a plurality of variable current electrical device manual controls accessible on a front panel of said control module;
c. at least one radio frequency transceiver within said control module;
d. at least one pair of input power coupling prongs extending through a backplate of said snap fit housing; and
e. at least one pair of output power coupling prongs extending through said backplate of said snap fit housing.

2. The system of claim 1, wherein said plurality of variable current electrical device manual controls enable the functions of:
a. power ON/OFF for said variable current electrical device;
b. increase current to said variable current electrical device;
c. decrease current to said variable current electrical device; and
d. select an output current variation pattern for said variable current electrical device.

3. The system of claim 2, comprising circuitry to receive, store, retrieve, and execute a power output pattern.

4. The system of claim 1, wherein said at least one radio frequency transceiver comprises a short-range radio transceiver.

5. The system of claim 1, wherein said at least one radio frequency transceiver comprises a cellular telephone transceiver.

6. The system of claim 1, comprising:
a. a device comprising:
i. radio frequency communication functionality; and
ii. a software application configured to run on said device; and
b. wherein said software application is configured, via said radio frequency communication functionality, to:
i. send commands to said control module to perform at least said functions of said plurality of manual controls; and
ii. receive communications from said control module responsive to said commands.

7. The system of claim 1, wherein said control module is configured to store at least one user-selectable said output power pattern.

8. The system of claim 1, comprising:
a. a front panel printed circuit board (PCB) supporting a plurality of mechanical push buttons alignable to a respective plurality of electro-mechanical switches mounted proximate and rearward of said front panel PCB;
b. a second PCB:
i. in electrical communication with said front panel PCB and said plurality of electro-mechanical switches;
ii. extending orthogonally rearward from said front panel PCB; and
iii. supporting said pair of output power coupling prongs, power MOSFETS, power output regulators, and pattern generation circuitry; and
c. a third PCB:
i. in electrical communication with said front panel PCB and said plurality of electro-mechanical switches;
ii. extending orthogonally rearward from said front panel PCB; and
iii. supporting said pair of input power coupling prongs, at least one radio frequency transceiver, and input power regulation circuitry.

9. The system of claim 1, comprising an insulator panel, within said snap fit housing, having a plurality of slots, wherein each said insulator slot is configured to conduct a respective one of said prongs.

10. The system of claim 1, comprising said backplate closing off said rear portion of said housing, wherein said backplate has a plurality of slots, each said back late slot is configured to conduct a respective one of said prongs.

11. A remotely controllable snap-in variable current electrical device controller system comprising:
a. a control module having a snap fit housing configured to engage a modular frame;
b. a plurality of manual controls accessible on a front panel of said control module;
c. at least one radio frequency transceiver within said control module;
d. at least one pair of input power coupling prongs extending through a backplate of said snap fit housing;
e. at least one pair of output power coupling prongs extending through said backplate of said snap fit housing; and
f. wherein said plurality of variable current electrical device manual controls enables the functions of:
i. power ON/OFF for said variable current electrical device;
ii. increase current to said variable current electrical device;
iii. decrease current to said variable current electrical device; and
iv. select a current variation pattern for said variable current electrical device.

12. The system of claim 11, comprising said control module configured to store at least one user-selectable said output power pattern.

13. The system of claim 11, wherein said at least one radio frequency transceiver comprises at least one of:
a. a short-range radio transceiver; and
b. a cellular telephone transceiver.

14. The system of claim 11, comprising:
a. a software application configured to run on a device that has radio frequency communication functionality; and
b. wherein said software application is configured, via said radio frequency communication functionality, to:
i. send commands to said control module to perform at least said functions of said plurality of high-power manual controls; and
ii. receive communications from said control module responsive to said commands.

15. The system of claim 11, wherein said controller is configured to store user-selectable output power patterns.

16. The system of claim 11, comprising:
a. a front panel printed circuit board (PCB) supporting mechanical push buttons alignable to respective electro-mechanical switches mounted proximate and rearward of said front panel PCB;
b. a second PCB:
i. in electrical communication with said front panel PCB and said electro-mechanical switches;
ii. extending orthogonally rearward from said front panel PCB; and
iii. supporting said pair of output power coupling prongs, power MOSFETS, power output regulators, and pattern generation circuitry; and
c. a third PCB:
i. in electrical communication with said front panel PCB and said electro-mechanical switches;
ii. extending orthogonally rearward from said front panel PCB; and
iii. supporting said pair of input power coupling prongs, at least one radio frequency transceiver, and input power regulation circuitry.

17. The system of claim 11, comprising an insulator panel within said housing, having a plurality of slots, wherein each said slot is configured to conduct a respective one of said prongs.

18. The system of claim 11, comprising said backplate closing off said rear portion of said housing, wherein said backplate has a plurality of slots, each said backplate slot configured to conduct a respective one of said prongs.

19. A remotely controllable snap-in variable current electrical device controller system comprising:
a. a control module having a snap fit housing configured to engage a modular frame;
b. a plurality of variable current electrical device manual controls accessible on a front panel of said control module;
c. at least one radio frequency transceiver within said control module;
d. at least one pair of input power coupling prongs extending through a backplate of said snap fit housing;
e. at least one pair of output power coupling prongs extending through said backplate of said snap fit housing;
f. wherein said plurality of variable current electrical device manual controls enables control signal output of the functions of:
i. power ON/OFF for said variable current electrical device;
ii. increase output current to said variable current electrical device;
iii. decrease output current to said variable current electrical device; and
iv. select an output current variation pattern for said variable current electrical device;
g. circuitry to receive, store, retrieve, and execute at least one said power variation output pattern;
h. wherein said at least one output current variation pattern comprises a plurality of user-selectable output current variation patterns;
i. wherein said at least one radio frequency transceiver comprises at least one of:
i. a short-range radio transceiver; and
ii. a cellular telephone transceiver;
j. a software application configured to run on a device that:
i. has radio frequency communication functionality; and
ii. wherein said software application is configured, via said radio frequency communication functionality, to send commands to said control module to perform at least said functions of said plurality of high-power manual controls; and
iii. receive communications from said control module responsive to said commands;
k. a front panel printed circuit board supporting a plurality of mechanical push buttons alignable to a respective plurality of electro-mechanical switches mounted proximate and rearward of said front panel PCB
l. a second PCB:
i. in electrical communication with said front panel PCB and said plurality of electro-mechanical switches;
ii. extending orthogonally rearward from said front panel PCB; and
iii. supporting said pair of output power coupling prongs, power MOSFETS, power output regulators, and pattern generation circuitry; and
m. a third PCB:
i. in electrical communication with said front panel PCB and said plurality of electro-mechanical switches;
ii. extending orthogonally rearward from said front panel PCB; and
iii. supporting said pair of input power coupling prongs, at least one radio frequency transceiver, and input power regulation circuitry.

20. The system of claim 19, comprising:
a. an insulator panel, within said snap fit housing, having a plurality of slots, wherein each said insulator slot is configured to conduct a respective one of said prongs; and
b. said backplate closing off said rear portion of said snap fit housing, wherein said backplate has a plurality of slots, each said slot configured to conduct a respective one of said prongs.
